(19) United States
(12) Patent Application Publication
(10) Pub. No.: US 2025/0098134 A1
(43) Pub. Date: Mar. 20, 2025

(54) MOUNTING SYSTEM AND MEMBER SUPPLY GUIDANCE METHOD

(71) Applicant: FUJI CORPORATION, Chiryu (JP)

(72) Inventor: Daisuke YAMANAKA, Kariya-shi (JP)

(73) Assignee: FUJI CORPORATION, Chiryu (JP)

(21) Appl. No.: 18/726,546

(22) PCT Filed: Feb. 15, 2022
(86) PCT No.: PCT/JP2022/005832

§ 371 Date: Jul. 3, 2024

(51) Int. Cl. H05K 13/02; H05K 13/04; H05K 13/08

(52) U.S. Cl. CPC H05K 13/021; H05K 13/0417; H05K 13/086

(57) ABSTRACT

A mounting system includes a mounting device, a moving operation device to move between a storage section and the mounting device to convey and supply members, an information acquisition section to acquire information including a usage status of the members in the mounting process, an operational status of the moving operation device, and a storage status of the storage section, a prediction section to predict a supply timing of the members, and predict a required time until a supply target member is conveyed from the storage section and supplied to the mounting device based on the operational status and the storage status, and a guidance output section to monitor whether supply of the members in the required time will be in time for the supply timing, and output guidance to a worker to supply the members when the members will not be in time.

### TECHNICAL FIELD

The present description discloses a mounting system and a member supply guidance method.

### BACKGROUND ART

Conventionally, there is known a mounting system including a mounting device on which a member such as a component supply unit used for a mounting process of a board is mounted, and an operation device (exchange device) that performs automatic exchange operation of the member (for example, refer to Patent Literature 1). In this mounting system, by making an exchange instruction of a member to be output to the operation device visible to a worker, not only the operation device but also the worker is instructed to perform an exchange operation of the member.

### Patent Literature

Patent Literature 1: WO2020/026379A1

### BRIEF SUMMARY

### Technical Problem

In the mounting system described above, while making the exchange instruction of the member visible to the worker, it does not actively encourage the exchange of the member. Therefore, the worker may choose to leave the exchange operation to the operation device without performing the exchange operation. However, when the worker has left the exchange operation to the operation device, depending on the work status of the operation device or the number of exchange target members, the members may not be supplied at a necessary supply timing. In this case, the production of the board may be interrupted due to waiting for supply of the member.

A main object of the present disclosure is to prevent interruption of production by prompting a worker to perform a supply operation when it is determined that supply of members by an operation device will not be in time.

### Solution to Problem

The present disclosure employs the following means in order to achieve the main object described above.

The mounting system of the present disclosure includes
a mounting device to which multiple members used in a mounting process are mounted, and a moving operation device configured to move between a storage section of the members and the mounting device to convey and supply the members, the mounting system including:
an information acquisition section configured to acquire information including a usage status of the members in the mounting process, an operational status of the moving operation device, and a storage status of the storage section;
a prediction section configured to predict a supply timing of the members based on the usage status of the members, and predict a required time until a supply target member is conveyed from the storage section and supplied to the mounting device by the moving operation device based on the operational status and the storage status; and
a guidance output section configured to monitor whether supply of the members in the required time will be in time for the supply timing, and output, when it is determined that the supply of the members will not be in time, guidance to a worker to supply the members.

The mounting system of the present disclosure is configured to predict the required time until the supply target member is conveyed from the storage section and supplied to the mounting device by the moving operation device, monitor whether the supply will be in time for the supply timing, and output, when it is determined that the supply will not be in time for the supply timing, guidance to the worker to supply the members. Accordingly, it is possible to prompt the worker to perform the supply operation by causing the worker to recognize that the supply of the members by the moving operation device will not be in time. Accordingly, when it is determined that the supply of the members by the moving operation device will not be in time, it is possible to prevent interruption of production by prompting the worker to perform a supply operation.

### BRIEF DESCRIPTION OF DRAWINGS

FIG. 1 is a view schematically illustrating a configuration of mounting system 10.

FIG. 2 is a view schematically illustrating a configuration of mounting device 20.

FIG. 3 is a block diagram illustrating a configuration related to control of mounting system 10.

FIG. 4 is a diagram illustrating an example of feeder information 54a.

FIG. 5 is a flowchart illustrating an example of a feeder supply-related process.

FIG. 6 is a flowchart illustrating an example of a supply delay prediction handling process.

FIG. 7 is a diagram illustrating an example of supply guidance when the supply delay is predicted.

FIG. 8 is a diagram illustrating an example of the supply guidance when the supply delay is predicted.

FIG. 9 is a flowchart illustrating an example of an automatic supply unavailability handling process.

### DESCRIPTION OF EMBODIMENTS

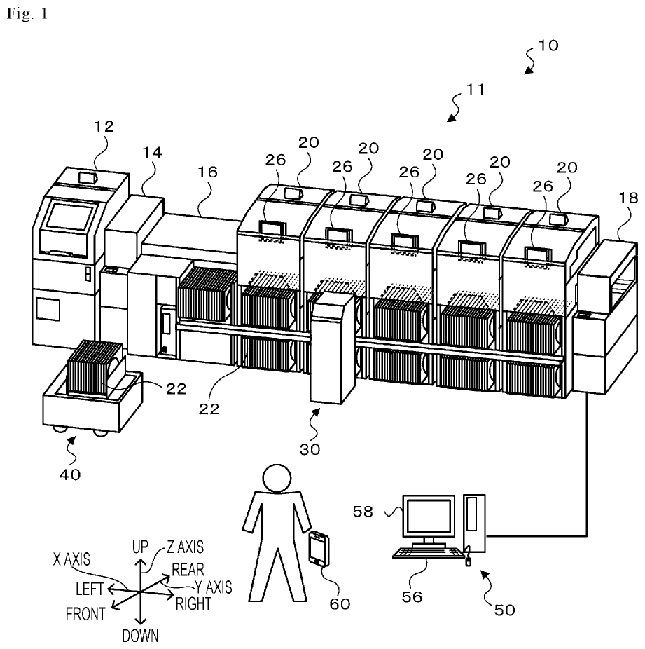

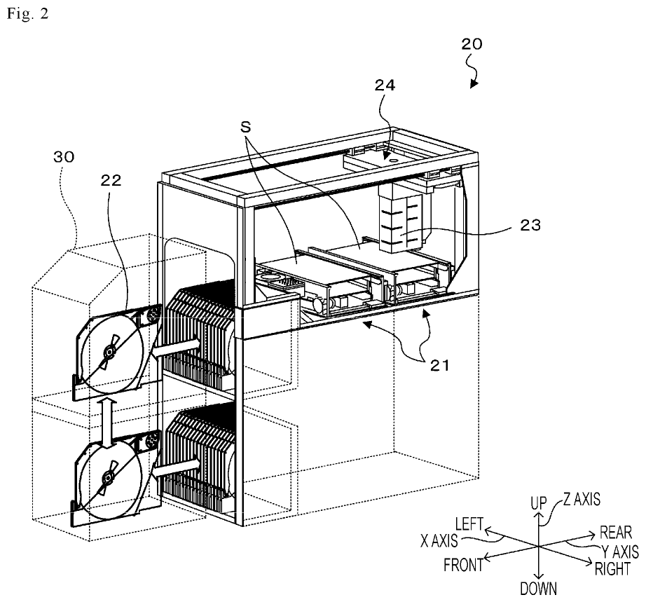

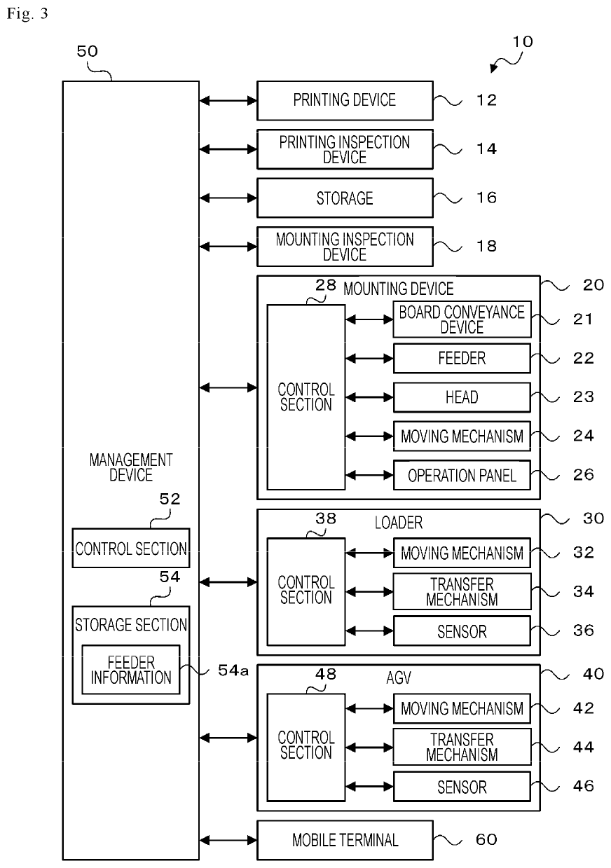

Next, an embodiment of the present disclosure will be described with reference to the drawings. FIG. 1 is a view schematically illustrating a configuration of mounting system 10. FIG. 2 is a view schematically illustrating a configuration of mounting device 20. FIG. 3 is a block diagram illustrating a configuration related to control of mounting system 10. In the present embodiment, a left-right direction (X axis), a front-rear direction (Y axis), and an up-down direction (Z axis) are as illustrated in FIGS. 1 and 2.

Mounting system 10 performs a mounting process of components on boards S (refer to FIG. 2) and includes mounting line 11, loader 30, automated guided vehicle 40 (hereinafter, AGV 40), and management device 50. Mounting line 11 includes printing device 12, printing inspection device 14, storage 16, mounting device 20, mounting inspection device 18, and the like. These are arranged in a conveyance direction of board S (an X-axis direction). Mounting line 11 may include a reflow device or the like that performs a reflow process of board S on which the components are mounted.

Printing device 12 prints on board S by pushing solder into pattern holes formed in a screen mask. Printing inspection device 14 inspects a state of the solder printed by printing device 12. Mounting inspection device 18 inspects the mounting state of components mounted on board S by mounting devices 20.

Multiple mounting devices 20 are arranged in the conveyance direction of board S and mount components on board S. Mounting device 20 includes board conveyance device 21, multiple feeders 22, head 23, moving mechanism 24, operation panel 26, and control section 28. Board conveyance device 21 has two pairs of conveyor belts and conveys board S by each conveyor belt. Therefore, mounting line 11 is configured to convey board S in two conveyor lanes parallel to each other, one in front and one behind. Board conveyance device 21 may be configured to have a pair of conveyor belts, and mounting line 11 may be configured to convey board S in one conveyor lane.

Feeder 22 is configured as a tape feeder that has a reel on which a tape holding a component in a predetermined pitch is wound and which feeds out the tape to supply the component by rotating the reel. Feeder 22 is detachably mounted on a loading table provided on the front surface of mounting device 20, and multiple feeders 22 are arranged and held in the X-axis direction. Head 23 is configured with pickup members such as nozzles, which can be lifted and lowered, and uses the pickup members to pick up a component and mount the component on board S. Moving mechanism 24 includes a slider that moves in an XY direction guided by guide rails, and a motor that drives the slider, and moves head 23 attached to the slider in the XY direction. Operation panel 26 includes a display section that displays various information and an operation section on which various types of input operations can be performed by a worker.

Control section 28 is configured with well-known CPU, ROM, RAM, and the like, and outputs drive signals to board conveyance device 21, each feeder 22, head 23, moving mechanism 24, and the like, and outputs display signals to operation panel 26. Control section 28 receives signals from board conveyance device 21, each feeder 22, head 23, moving mechanism 24, and the like, and receives operation signals from operation panel 26.

Storage 16 is an in-line storage for storing feeder 22 used in the mounting process in mounting line 11. The worker supplies or retrieves feeder 22 in storage 16. Further, in storage 16, loader 30 and AGV 40 are configured to automatically exchange feeder 22, and supply or retrieve feeder 22.

Loader 30 includes moving mechanism 32, transfer mechanism 34, sensor 36, and control section 38. Moving mechanism 32 is configured to move loader 30 in the left-right direction along the conveyance direction of board S on the front surface side of multiple mounting devices 20 and storage 16. Although not illustrated, transfer mechanism 34 includes a clamp mechanism that clamps feeder 22, a clamp moving mechanism that moves the clamp mechanism in the front-rear direction or the up-down direction, and the like, and is configured to transfer feeder 22 between loader 30 and mounting device 20 or storage 16. As sensor 36, a detection sensor that detects a worker or an object within a predetermined detection range in the advancement direction (left direction or right direction) of loader 30, a position sensor that detects a movement position, or the like is provided.

Control section 38 is configured with well-known CPU, ROM, RAM, and the like, receives various detection signals from sensor 36, and outputs drive signals to moving mechanism 32 and transfer mechanism 34. When feeder 22 is automatically exchanged, control section 38 causes moving mechanism 32 to move loader 30 at a position facing mounting device 20 having feeder 22 to be exchanged as a target position. When loader 30 arrives at the target position, control section 38 causes transfer mechanism 34 to pull out and retrieve feeder 22 mounted on mounting device 20. Further, control section 38 causes transfer mechanism 34 to feed out new feeder 22 in loader 30 and mount new feeder 22 on mounting device 20. When an obstacle, such as a worker or an object, is detected by sensor 36 during traveling of loader 30, control section 38 causes moving mechanism 32 to stop traveling of loader 30 until the obstacle is no longer detected.

AGV 40 includes traveling mechanism 42, transfer mechanism 44, sensor 46, and control section 48. Traveling mechanism 42 automatically travels AGV 40 between mounting line 11 and a warehouse of feeder 22, and includes, although not illustrated, a motor that rotates and drives the wheels, a battery that supplies power, and the like. Transfer mechanism 44 is configured to transfer the pallet equipped with feeder 22 between storage 16 and a warehouse. As sensor 46, a detection sensor that detects a worker or an object within a front detection range in the advancement direction of AGV 40, a position sensor that detects a traveling position, or the like is provided.

Control section 48 is configured with well-known CPU, ROM, RAM, and the like, and receives various detection signals from sensor 46. In addition, control section 48 outputs drive signals to traveling mechanism 42 to travel toward a destination, such as storage 16 or a warehouse, and outputs drive signals to transfer mechanism 44 to transfer the pallet equipped with feeder 22 between storage 16 and the warehouse. When an obstacle, such as a worker or an object, is detected by sensor 46 during automatic traveling, control section 48 causes traveling mechanism 42 to stop traveling of AGV 40 until the obstacle is no longer detected.

Management device 50 is a general-purpose computer including control section 52 configured with well-known CPU, ROM, RAM, and the like, and storage section 54 such as HDD that stores various information, with input device 56, such as a keyboard or a mouse, and output device 58 such as a display connected. In addition to the production program of board S, storage section 54 stores feeder information 54a indicating a usage status, an inventory status, and the like of feeder 22. The production program includes information such as the production quantity of board S, the printing position of solder on board S, and the type, mounting position, and the mounting order of the component to be mounted on board S. When producing board S, management device 50 outputs various command signals to the devices, such as printing device 12, printing inspection device 14, mounting device 20, and mounting inspection device 18, based on the production program, and inputs the work status from each device. Further, management device 50 outputs supply guidance for supplying feeder 22 to mounting device 20 to loader 30, and inputs an operational status of loader 30. Management device 50 is configured to wirelessly communicate with AGV 40, outputs a traveling instruction to AGV 40, and inputs a traveling status of AGV 40. Management device 50 is configured to communicate with mobile terminal 60 carried by a worker, outputs various information displayed on the display screen of mobile terminal 60, and inputs information input by mobile terminal 60 or information read by mobile terminal 60.

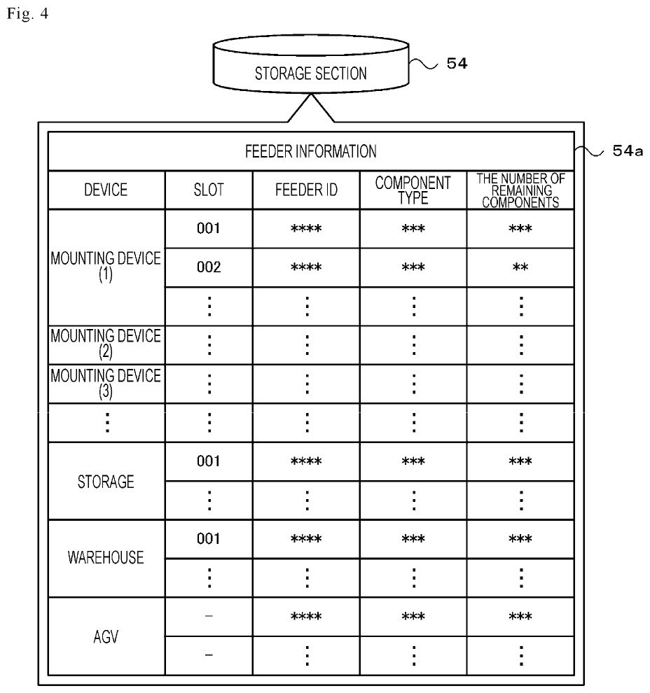

Here, FIG. 4 is a diagram illustrating an example of feeder information 54a. Feeder information 54a includes information relating to an arrangement position of feeder 22, a feeder ID which is identification information of feeder 22, a component type of components accommodated in feeder 22, the number of remaining components, and the like. The information on the arrangement position includes information on which of mounting device 20, storage 16, the warehouse, and AGV 40 feeder 22 is arranged in, and which slot feeder 22 is mounted in. The fact that feeder 22 is arranged in AGV 40 indicates that feeder 22 is being conveyed by AGV 40. Management device 50 appropriately updates feeder information 54a through communication with various devices, such as each mounting device 20, storage 16, mobile terminal 60 of the worker in the warehouse, and the warehouse management device.

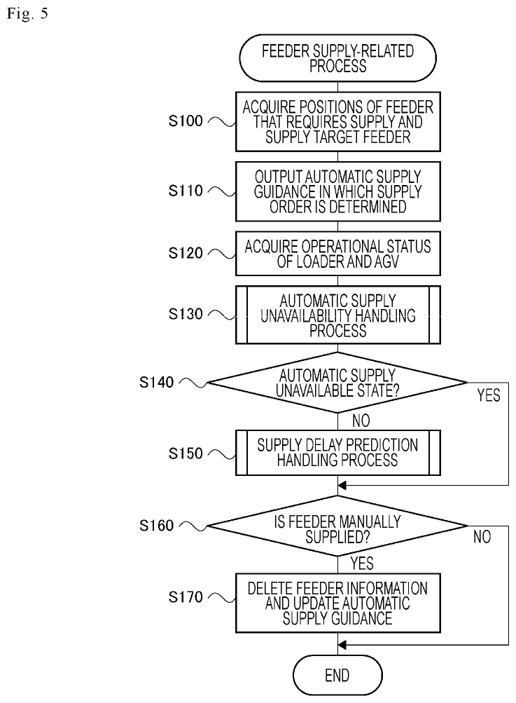

The following is a description of the operation of mounting system 10 configured as above. FIG. 5 is a flowchart illustrating an example of a feeder supply-related process. This process is executed by control section 52 of management device 50. In this process, control section 52 first acquires position information on feeder 22 that requires supply and supply target feeder 22 that is to be exchanged with feeder 22 from feeder information 54a (S100). Control section 52 acquires, for example, information on the number of remaining components in feeder 22 attached to each mounting device 20, specifies feeder 22, for which supply (exchange) is predicted to be required, and acquires the position (slot number) thereof. Feeder 22 that is predicted to require supply is, for example, feeder 22 that is close to running out of components when the number of remaining components is below a predetermined number near a value of 0. In addition, control section 52 may acquire information on the production status of each device to predict the changeover of board types, and specify feeder 22 that is predicted to require supply due to the setup change accompanying the changeover. Hereinafter, feeder 22 that is predicted to require supply is referred to as feeder 22 that requires supply. In the case of exchange due to running out of components, supply target feeder 22 is feeder 22 of the same component type as feeder 22 that requires supply, and information on the location such as the storage position (slot number) of storage 16 is acquired. The process when the location of supply target feeder 22 is unknown will be described later.

Next, control section 52 updates the automatic supply guidance in which the supply order of feeders 22 that requires supply is determined, and outputs the updated automatic supply guidance to loader 30 (S110). Control section 52 may skip the process of S110 when there is no new feeder 22 that requires supply. Although not illustrated, the automatic supply guidance includes information, for each feeder 22 that requires supply, such as the identification number (module number) and the slot number of mounting device 20, the information of the feeder ID, and the information on newly mounted supply target feeder 22, such as the feeder ID and the location information, such as the storage position. Loader 30 performs automatic supply of feeder 22 according to the supply order of the automatic supply guidance. When supply target feeder 22 is in storage 16, loader 30 moves to storage 16, takes out supply target feeder 22 from storage 16, and then moves to target mounting device 20. Then, loader 30 removes feeder 22 that requires supply from target mounting device 20, and then attaches supply target feeder 22, thereby performing automatic supply of feeder 22. When the automatic supply of feeder 22 is performed, the information of feeder 22 is deleted from the automatic supply guidance.

Next, control section 52 acquires the operational status of loader 30 and AGV 40 (S120). In S120, control section 52 acquires information on the current position of loader 30, information on feeder 22 during the supply operation, information on the current position of AGV 40, information on feeder 22 being conveyed, information on an operational error, such as loader 30 or AGV 40 being stopped due to obstacle detection. Subsequently, control section 52 executes an automatic supply unavailability handling process (S130), and determines whether a state is in an automatic supply unavailable state in which an automatic supply by loader 30 is not possible (S140). The automatic supply unavailable state is a state in which automatic supply of feeder 22 cannot be performed because, for example, there is an operational error occurring in loader 30 or AGV 40, or the location of supply target feeder 22 is unknown. In S130, control section 52 performs a process when the automatic supply unavailable state occurs, a process when the automatic supply unavailable state returns to the normal state, and the like, and details thereof will be described later. When it is determined in S140 that a state is not in the automatic supply unavailable state, control section 52 executes a supply delay prediction handling process (S150), and proceeds to S160 and when it is determined in S140 that a state is in the automatic supply unavailable state, control section 52 skips S150 and proceeds to S160.

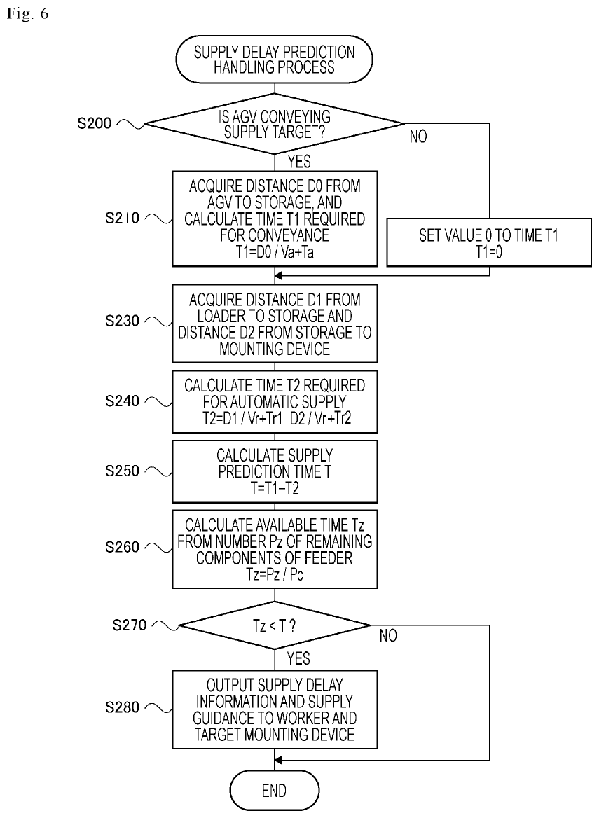

FIG. 6 is a flowchart illustrating an example of a supply delay prediction handling process. This process prompts the worker to manually supply feeder 22 in which the supply delay is predicted among feeders 22 supplied according to the supply order of the automatic supply guidance. In this process, control section 52 first determines whether AGV 40 is conveying supply target feeder 22 based on the position information of feeder 22 acquired in S100 (S200). When it is determined that AGV 40 is conveying feeder 22, control section 52 acquires distance D0 from the position of AGV 40 acquired in S120 to storage 16, calculates time T1 required for conveying feeder 22 (S210), and proceeds to S230. For example, control section 52 calculates the moving time to storage 16 by dividing distance D0 by average moving speed Va of AGV 40, and calculates time T1 by adding transfer time Ta of feeder 22 (pallet) in storage 16 to the moving time. Average moving speed Va may be an actual measurement value calculated from an actual moving speed or a specified value. On the other hand, when it is determined in S200 that AGV 40 is not conveying supply target feeder 22 and storage 16 is storing supply target feeder 22, control section 52 sets the value 0 to time T1 (S220) and proceeds to S230.

Next, control section 52 acquires distance D1 from the position of loader 30 to storage 16 and distance D2 from storage 16 to supply target mounting device 20 (S230), and calculates time T2 required for automatic supply of feeder 22 by loader 30 (S240). The position of loader 30 is, for example, the current position of loader 30 acquired in S120. When loader 30 is in process of automatically supplying feeder 22 with a prior supply order, since loader 30 moves from the position where feeder 22 is supplied (exchanged) to storage 16, the position may be used. Further, for example, control section 52 calculates the moving time to storage 16 by dividing distance D1 by average moving speed Vr of loader 30, and calculates the moving time to supply target mounting device 20 by dividing distance D2 by average moving speed Vr. Control section 52 calculates time T2 by adding transfer time Tr1 of feeder 22 in storage 16 and transfer time Tr2 of feeder 22 in mounting device 20 to these moving times. Average moving speed Vr may be an actual measurement value or a specified value. Transfer times Tr1 and Tr2 may be different from each other, such as actual measurement values required for each operation, or may be the same as each other.

Subsequently, control section 52 calculates the sum of time T1 and time T2 as supply prediction time T (S250), and calculates available time (available production time) Tz from number Pz of remaining components of feeder 22 that requires supply (S260). Supply prediction time T is predicted as a required time until supply target feeder 22 is supplied to the slot of mounting device 20 based on the operational status of loader 30 or AGV 40 or the storage status of feeder 22. When the process of S220 is performed, since the value 0 is set to time T1, supply prediction time T becomes time T2. Alternatively, supply prediction time T may be calculated by adding a margin a to the sum of time T1 and time T2. Meanwhile, available time Tz is calculated by dividing number Pz of remaining components by number Pc of mounted components per unit time. Number Pc of mounted components may be a value determined in advance according to the board type or the component type, or may be a value calculated based on the production status of mounting device 20. Available time Tz refers to the remaining time until feeder 22 runs out of components, and is predicted as a supply timing at which supply of feeder 22 is required.

Then, control section 52 determines whether available time Tz is less than supply prediction time T (S 270). This determination is a process of monitoring whether the supply at supply prediction time T (required time) will be in time for available time Tz (supply timing). When it is determined that available time Tz is less than supply prediction time T, that is, the supply of feeder 22 will not be in time, control section 52 outputs supply delay information of feeder 22 and the supply guidance to mobile terminal 60 of the worker and target mounting device 20 (S280), and ends the supply delay prediction handling process. On the other hand, when it is determined that available time Tz is not less than supply prediction time T, that is, the supply of feeder 22 will be in time, control section 52 skips S280 and ends the process.

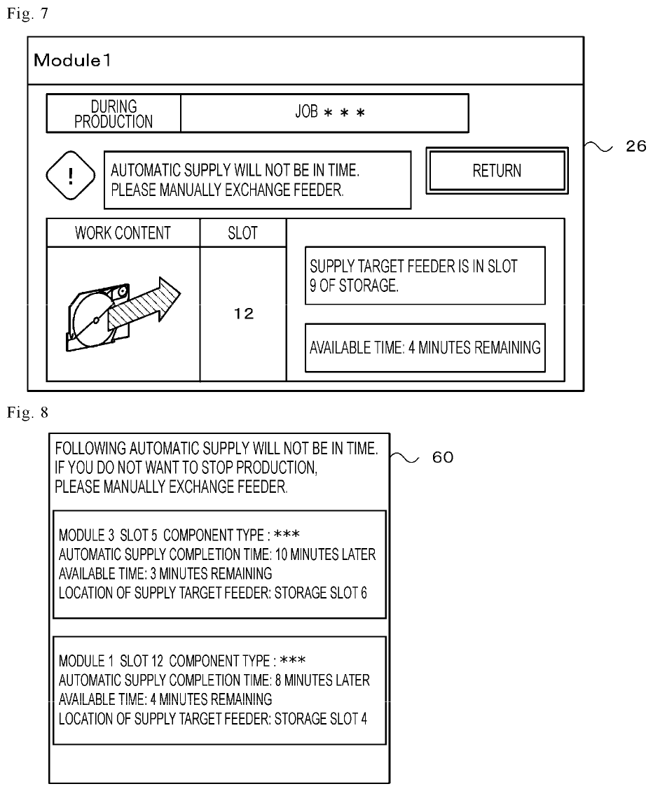

Here, FIG. 7 and FIG. 8 are diagrams illustrating an example of supply guidance when the supply delay is predicted. FIG. 7 is supply guidance displayed on operation panel 26 of mounting device 20, and illustrates the supply guidance in mounting device 20(1) (module 1). As illustrated in the drawing, information that the automatic supply will not be in time and information prompting the worker to manually exchange the feeder are displayed. The slot number of feeder 22 that requires supply, the location information (slot number of storage 16) of supply target feeder 22, and the available time of feeder 22 that requires supply are displayed. With this supply guidance, the worker can be prompted to manually supply feeder 22 within the available time.

FIG. 8 is supply guidance displayed on mobile terminal 60 of the worker, and illustrates the supply guidance for mounting devices 20(1) and 20(3) (modules 1 and 3). In the supply guidance, the necessary supply operations for each mounting device 20 are displayed in order of increasing available time, that is, in order of increasing remaining time. In each guidance, the module number and the slot number of mounting device 20 that requires manual supply, the automatic supply completion time indicating supply prediction time T, the available time of feeder 22 that requires supply, and the location information of supply target feeder 22 are displayed. With this supply guidance, it is possible to cause the worker to grasp the supply order of feeders 22 and subsequently perform manual supply.

In the feeder supply-related process of FIG. 5, when control section 52 executes the supply delay prediction handling process (S150) or skips S150, control section 52 determines whether the manual supply of feeder 22 is performed by the worker (S160). When it is determined that the manual supply is not performed, control section 52 ends the feeder supply-related process. On the other hand, when it is determined that the manual supply is performed, control section 52 updates the automatic supply guidance by deleting the information of feeder 22 (S170), and ends the feeder supply-related process. Accordingly, since it is possible to prevent loader 30 from automatically supplying feeder 22 which has been manually supplied, it is possible to appropriately perform the cooperative work of the manual supply of the worker and the automatic supply of loader 30.

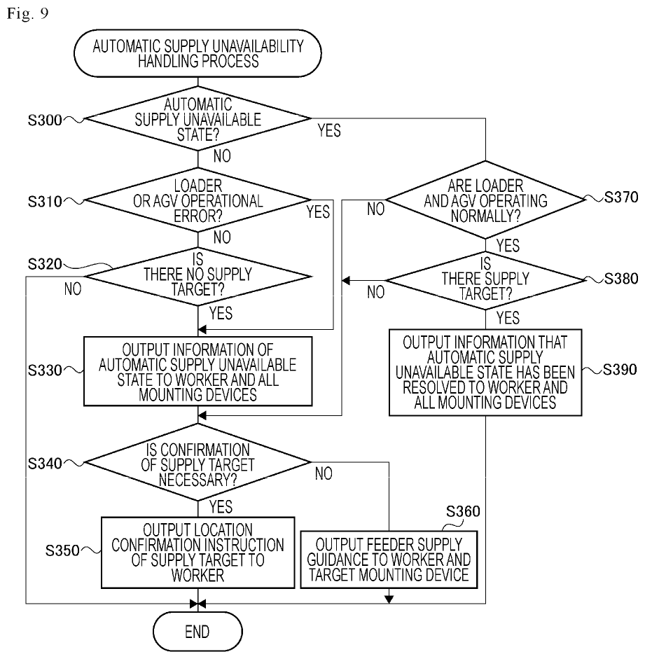

Next, the automatic supply unavailability handling process of S130 will be described. FIG. 9 is a flowchart illustrating an example of an automatic supply unavailability handling process. In this process, control section 52 determines whether a state is in the automatic supply unavailable state (S300), and when it is determined that a state is not in the automatic supply unavailable state, control section 52 determines whether an operational error has occurred in loader 30 or AGV 40 (S310), and whether there is no supply target feeder 22 (S320). In S320, it is determined that there is no supply target feeder 22 when the location of supply target feeder 22 is unknown, or the like. When it is determined that the operational error of loader 30 or AGV 40 has not occurred and there is supply target feeder 22, control section 52 ends the automatic supply unavailability handling process.

On the other hand, when it is determined in S310 that the operational error has occurred or when it is determined in S320 that there is no supply target feeder 22, control section 52 outputs information that a state is in the automatic supply unavailable state to all mounting devices 20 and mobile terminal 60 of the worker (S330). Further, control section 52 determines whether confirmation of supply target feeder 22 is necessary (S340). In S340, it is determined that the confirmation (search) of feeder 22 by the worker is necessary when the location of supply target feeder 22 is unknown. When it is determined that the confirmation is necessary, control section 52 outputs a location confirmation instruction of supply target feeder 22 to mobile terminal 60 of the worker (S350), and ends the automatic supply unavailability handling process. The worker who has received this instruction performs operations such as searching for supply target feeder 22 in a warehouse or a work field around the warehouse to confirm the location of supply target feeder 22, or newly incorporating a reel accommodating components of a necessary component type into feeder 22 to make feeder 22 the supply target.

On the other hand, when it is determined that the confirmation is not necessary in S340 because the location of supply target feeder 22 is clear, control section 52 outputs the supply guidance of feeder 22 to mobile terminal 60 of the worker and target mounting device 20 (S360), and ends the automatic supply unavailability handling process. Mounting device 20 that has received the supply guidance displays the supply guidance, including information that a state is in the automatic supply unavailable state, on operation panel 26. Although the supply guidance is not illustrated, for example, in the supply guidance of FIG. 7, information that automatic supply will not be in time is replaced with information that a state is in the supply unavailable state, while the rest is displayed with same content. Similarly, mobile terminal 60 that has received the supply guidance in S360 displays the supply guidance including information that a state is in the automatic supply unavailable state. Accordingly, even in the automatic supply unavailable state, the manual supply of feeder 22 can be prompted similar to when the supply delay is predicted. In the automatic supply unavailable state, supply prediction time T cannot be predicted because it is unknown when the operational error returns to the normal state or the location of feeder 22. Therefore, although the manual supply of feeder 22 cannot be prompted in the supply delay prediction handling process, the manual supply can be appropriately prompted in the automatic supply unavailability handling process.

When it is determined that a state is in the automatic supply unavailable state in S300, control section 52 determines whether the operational errors in loader 30 and AGV 40 have been resolved and the operation is normal (S370) and whether there is supply target feeder 22 (S380). When it is determined that the operation of loader 30 or AGV 40 is not normal or there is no supply target feeder 22, control section 52 proceeds to S340 and performs the process of S350 or S360. When it is determined that the operation of loader 30 and AGV 40 is normal and there is supply target feeder 22, control section 52 determines that the automatic supply unavailable state has been resolved, and outputs this information to all mounting devices 20 and mobile terminal 60 of the worker (S390), and ends the automatic supply unavailability handling process.

Here, a correspondence relationship between the elements of the present embodiment and the elements of the present disclosure will be clarified. Mounting system 10 of the present embodiment corresponds to a mounting system of the present disclosure, control section 52 of management device 50 that executes S100 and S120 of the feeder supply-related process corresponds to an information acquisition section, control section 52 that executes S200 to S260 of the supply delay prediction handling process corresponds to a prediction section, and control section 52 that executes S270 and S280 of the same process corresponds to a guidance output section. In the present embodiment, an example of member supply guidance method is also clarified by describing an operation of mounting system 10.

Mounting system 10 described above is configured to calculate supply prediction time T until supply target feeder 22 is automatically supplied, and monitor whether the supply will be in time for the supply timing, compared with available time Tz of feeder 22, and output supply guidance to a worker when the supply is not in time for the supply timing. Accordingly, it is possible to prompt the worker to perform the manual supply by causing the worker to recognize that the automatic supply of feeder 22 by loader 30 will not be in time. Accordingly, when the automatic supply of feeder 22 will not be in time, it is possible to prevent interruption of production due to running out of components.

Further, the time (D1/Vr) for loader 30 to move to storage 16, the time (Tr1) to take out feeder 22 from the storage position, the time (D2/Vr) for loader 30 to move to mounting device 20, and the time (Tr2) to mount feeder 22 on mounting device 20 are summed up to calculate time T2 required for automatic supply. Since supply prediction time T includes time T2, it is possible to accurately predict supply prediction time T and appropriately monitor whether the supply will be in time.

Further, when feeder 22 is manually supplied by the worker, since the automatic supply guidance is updated to delete feeder 22, the cooperative work of the automatic supply of loader 30 and the manual supply of the worker can be appropriately performed.

Further, even when supply prediction time T cannot be predicted because the operational error in loader 30 or AGV 40 occurs or there is no supply target feeder 22, the worker is guided to manually supply feeder 22. Therefore, it is possible to prevent interruption of production due to running out of components.

When AGV 40 is conveying supply target feeder 22, supply prediction time T is calculated, including time T1, which is the sum of a time (D0/Va) for AGV 40 to move to storage 16 and a time (Ta) to transfer (store) feeder 22 to storage 16. Therefore, even when AGV 40 is conveying supply target feeder 22, it is possible to accurately predict supply prediction time T and appropriately monitor whether the supply will be in time for the supply timing.

It is needless to say that the present disclosure is not limited to the embodiment described above in any way, and hence can be implemented in various aspects as long as the aspects fall within the technical scope of the present disclosure.

For example, in the embodiment, when AGV 40 is conveying feeder 22, supply prediction time T is calculated, including time T1, which is the sum of the time for AGV 40 to move to storage 16 and the time to transfer feeder 22, but the present disclosure is not limited thereto. For example, when AGV 40 is conveying feeder 22, supply prediction time T need not be calculated. That is, supply prediction time T may be calculated only targeting for feeder 22 stored in storage 16, or time T2 may be used as supply prediction time T as it is. Further, although the automatic supply unavailable state is set when the operational error has occurred in loader 30 or AGV 40, the operational error of AGV 40 need not be included. In this way, the present disclosure may be applied to mounting system 10 that does not include AGV 40.

In the embodiment, the manual supply is guided to the worker both in the case where the operational error has occurred in loader 30 or the like and in the case where there is no supply target feeder 22. However, the present disclosure is not limited thereto, and the manual supply may be guided to the worker in either case. Alternatively, it may be acceptable to simply notify without guiding manual supply in these cases. That is, the manual supply may be guided to the worker only when it is determined that the automatic supply of feeder 22 will not be in time.

In the embodiment, when calculating time T2 required for automatic supply, the moving time for loader 30 to move to storage 16 and the moving time to move to mounting device 20 are calculated by dividing distances D1 and D2 by average moving speed Vr, respectively, but the present disclosure is not limited thereto. For example, the moving time to storage 16 or the moving time to mounting device 20 may be determined in advance according to the position of loader 30 or the position of mounting device 20. That is, time T2 until supply target feeder 22 is conveyed from storage 16 and supplied to mounting device 20 may be predicted based on the work status of loader 30 and the storage status of feeder 22.

In the embodiment, supply of feeder 22 (component supply unit) is exemplified, but the present disclosure is not limited thereto, and supply of members used in the mounting process of the board in the mounting device may be acceptable. For example, supply (exchange) of heads or nozzles detachably mounted to mounting device 20 may also be acceptable. Further, it may also be acceptable for supply of members used in the mounting process of the board in the mounting-related devices, such as masks detachably mounted to printing device 12, not only in mounting device 20.

Here, the mounting system in the present disclosure may be configured as follows. For example, in the mounting system of the present disclosure, the information acquisition section may be configured to acquire information on a mounting position of the member that requires supply in the mounting device and information on a storage position of the member stored in the storage section, and the prediction section may be configured to predict the required time by summing up a time for the moving operation device to move to the storage section, a time to take out the supply target member from the storage position, a time to convey the supply target member from the storage section to the mounting device, and a time to supply or exchange the supply target member to the mounting position. In this way, it is possible to accurately predict the required time and appropriately monitor whether the supply will be in time for the supply timing.

In the mounting system of the present disclosure, the guidance output section may be configured to output supply guidance that determines a supply order of the members to the moving operation device, and update, when the worker is guided to supply the members, the supply guidance to delete the members from the supply order when the members are supplied based on the guidance. In this way, it is possible to appropriately perform the cooperative work of the supply of members by the moving operation device and the supply of members by the worker.

In the mounting system of the present disclosure, the guidance output section may be configured to guide the worker to supply the members even when the prediction section is unable to predict the required time due to acquisition of at least one piece of information, indicating an operational error of the moving operation device or indicating that there is no supply target member, obtained by the information acquisition section. In this way, even when the required time cannot be predicted, the supply operation can be promoted.

In the mounting system of the present disclosure, the storage section may be configured to store the members conveyed by an automated conveyance vehicle, the information acquisition section may be configured to acquire a conveyance status of the automated conveyance vehicle, and the prediction section may be configured to, when the supply target member is being conveyed to the storage section by the automated conveyance vehicle based on the conveyance status, predict the required time including a time for the automated conveyance vehicle to move to the storage section and a time to store the members in the storage section. In this way, even when the supply target member is being conveyed by the automated conveyance vehicle, it is possible to accurately predict the required time and appropriately monitor whether the supply will be in time for the supply timing.

The member supply guidance method of the present disclosure is a member supply guidance method in a mounting system including a mounting device to which multiple members used in a mounting process are attached, and a moving operation device configured to move between a storage section of the members and the mounting device to convey and supply the members, the method including: (a) a step of acquiring information including a usage status and scheduled usage of the members in the mounting process, an operational status of the moving operation device, and a storage status of the storage section; (b) a step of predicting a supply timing of the members based on the usage status and the scheduled usage of the members, and predicting a required time until a supply target member is conveyed from the storage section and supplied to the mounting device by the moving operation device based on the operational status and the storage status; and (c) a step of monitoring whether supply of the members in the required time is in time for the supply timing, and when it is determined that the supply of the members will not be in time, guiding a worker to supply the members.

In the member supply guidance method of the present disclosure, similarly to the mounting system described above, when it is determined that supply of the members by the moving operation device will not be in time, it is possible to prevent interruption of production by prompting the worker to perform the supply operation. In the member supply guidance method, various aspects of the mounting system described above may be adopted, or steps to achieve each function of the mounting system described above may be added.

### INDUSTRIAL APPLICABILITY

The present disclosure can be used in a mounting system or the like in which mounting devices, on which members are supplied by a moving operation device, are arranged.

### REFERENCE SIGNS LIST

10: mounting system, 11: mounting line, 12: printing device, 14: printing inspection device, 16: storage, 18: mounting inspection device, 20: mounting device, 21: board conveyance device, 22: feeder, 23: head, 24: moving mechanism, 26: operation panel, 28, 38, 48, 52: control section, 30: loader, 32: moving mechanism, 34, 44: transfer mechanism, 36, 46: sensor, 40: automated guided vehicle (AGV), 42: traveling mechanism, 50: management device, 54: storage section, 54a: feeder information, 56: input device, 58: output device, 60: mobile terminal, and S: board

1. A mounting system comprising a mounting device to which multiple members used in a mounting process are mounted, and a moving operation device configured to move between a storage section of the members and the mounting device to convey and supply the members, the mounting system comprising:
an information acquisition section configured to acquire information including a usage status of the members in the mounting process, an operational status of the moving operation device, and a storage status of the storage section;
a prediction section configured to predict a supply timing of the members based on the usage status of the members, and predict a required time until a supply target member is conveyed from the storage section and supplied to the mounting device by the moving operation device based on the operational status and the storage status; and
a guidance output section configured to monitor whether supply of the members in the required time will be in time for the supply timing, and output, when it is determined that the supply of the members will not be in time, guidance to a worker to supply the members.

2. The mounting system according to claim 1,
wherein the information acquisition section is configured to acquire information on a mounting position of the member that requires supply in the mounting device and information on a storage position of the member stored in the storage section, and
the prediction section is configured to predict the required time by summing up a time for the moving operation device to move to the storage section, a time to take out the supply target member from the storage position, a time to convey the supply target member from the storage section to the mounting device, and a time to supply or exchange the supply target member to the mounting position.

3. The mounting system according to claim 1,
wherein the guidance output section is configured to output supply guidance that determines a supply order of the members to the moving operation device, and update, when the worker is guided to supply the members, the supply guidance to delete the members from the supply order when the members are supplied based on the guidance.

4. The mounting system according to claim 1,
wherein the guidance output section is configured to guide the worker to supply the members even when the prediction section is unable to predict the required time due to acquisition of at least one piece of information, indicating an operational error of the moving operation device or indicating that there is no supply target member, obtained by the information acquisition section.

5. The mounting system according to claim 1,
wherein the storage section is configured to store the members conveyed by an automated conveyance vehicle,
the information acquisition section is configured to acquire a conveyance status of the automated conveyance vehicle, and
the prediction section is configured to, when the supply target member is being conveyed to the storage section by the automated conveyance vehicle based on the conveyance status, predict the required time including a time for the automated conveyance vehicle to move to the storage section and a time to store the members in the storage section.

6. A member supply guidance method in a mounting system including a mounting device to which multiple members used in a mounting process are mounted, and a moving operation device configured to move between a storage section of the members and the mounting device to convey and supply the members, the method comprising:
(a) a step of acquiring information including a usage status of the members in the mounting process, an operational status of the moving operation device, and a storage status of the storage section;
(b) a step of predicting a supply timing of the members based on the usage status of the members, and predicting a required time until a supply target member is conveyed from the storage section and supplied to the mounting device by the moving operation device based on the operational status and the storage status; and
(c) a step of monitoring whether supply of the members in the required time will be in time for the supply timing, and when it is determined that the supply of the members will not be in time, guiding a worker to supply the members.
